(19) United States
(12) Patent Application Publication
(10) Pub. No.: US 2008/0121412 A1
(43) Pub. Date: May 29, 2008

(54) WIRING PATTERN FORMING METHOD, DEVICE AND ELECTRONIC APPARATUS

(75) Inventors: Jun YAMADA, Shiojiri (JP); Junichiro SHINOZAKI, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/946,098

(22) Filed: Nov. 28, 2007

(30) Foreign Application Priority Data
Nov. 29, 2006 (JP) 2006-321472

(51) Int. Cl. H05K 1/00; B05D 5/12

(52) U.S. Cl. 174/250; 427/98.4

(57) ABSTRACT

A wiring pattern forming method comprises: relatively moving a droplet discharging head and a substrate, each in a predetermined direction; discharging a liquid material in a form of droplet onto the substrate from a plurality of discharging nozzles formed on the droplet discharging head; forming a predetermined wiring pattern on the substrate; and forming an end portion of a wiring pattern in a tapered shape, or a bent portion of a wiring pattern in a curved shape.

### BACKGROUND OF THE INVENTION

1. Technical Field

The present invention relates to a wiring pattern forming method in which a predetermined wiring pattern is formed with a liquid material discharged from a droplet discharging head onto a substrate.

2. Related Art

In recent years, use of the droplet discharging method has been started in the manufacture of various products including printed wirings, organic electroluminescent (EL) elements, and so on, because the method is finely controllable in spite of its high workability and reasonable cost.

In the past, the lithographic method has been employed for formation of wiring patterns used in electronic circuits, integrates circuits, or the like. However, the lithographic method is disadvantageous in that it requires a large scale facility, such as a vacuum equipment, as well as a complex process. Also, with its material use efficiency being not more than a few percent, the lithographic method necessitates disposal of most of the material used. All this has significantly increased the manufacturing cost of the method. Thus, a consideration has been started regarding use of the droplet discharging method as an alternative process to substitute for the lithographic method, because the droplet discharging method permits a liquid containing high performance material to be discharged in the form of droplets for direct patterning on a substrate.

To give an example, U.S. Pat. No. 5,132,248 discloses a technique that uses a droplet discharging method to apply a liquid containing dispersed fine conductive particles on a substrate for direct patterning there, and subsequently converts the discharged liquid into a conductive film pattern using heat processing or laser irradiation in order to form a wiring pattern.

Furthermore, JP-A-2004-146796 discloses that, in the process for forming a wiring pattern by the droplet discharging method, disconnection and short circuit can be prevented through a predetermined pretreatment performed on a substrate and improvement of the way the droplets land.

However, even in a wiring pattern formed in the above described manner, migration has sometimes occurred from an electric field between lines and caused dendrites, as shown in FIG. 1, when electric currents of different voltage polarities are flowed in adjacent lines. Particularly, migration is apt to occur at a portion of wiring pattern where the formal outline of the wiring pattern is angular. For example, migration tends to occur at a bent portion or an end portion of a wiring pattern. In the case where the bent portion or the end portion of a wiring pattern lies adjacent to another wiring pattern and if currents are flowed in the wiring patterns, a dendrite having grown may reach the other wiring pattern to cause short circuit between the wiring patterns.

### SUMMARY

An advantage of the invention is to provide a wiring pattern forming method using a droplet discharging method that allows migration to be restrained from occurring at an end portion or a bent portion of a wiring pattern, thereby either restraining the occurrence of dendrites or controlling the growth direction of dendrites, thus allowing prevention of short circuit between lines.

A wiring pattern forming method according to one aspect of the invention includes relatively moving a droplet discharging head and a substrate in predetermined directions; discharging droplets of a liquid material onto the substrate from a plurality of discharging nozzles formed on the droplet discharging head; forming a predetermined wiring pattern on the substrate; and forming an end portion of a wiring pattern in a tapered shape, or a bent portion of a wiring pattern in a curved shape.

Furthermore, the wiring pattern forming method may include step by step decreasing the number of droplets discharged in the scan direction of the wiring pattern while step by step shifting the position of discharged droplets in the non-scan direction of the wiring pattern by as much as half a pitch per droplet.

The wiring pattern forming method may further include increasing or decreasing the number of droplets discharged at the bent portion of the wiring pattern, thereby forming the bent portion in a curved shape.

In particular, the method may be used where currents of different voltage polarities are flowed in adjacent wiring patterns.

A device according to another aspect of the invention includes a predetermined wiring pattern that is formed on a substrate by the above wiring pattern forming method.

An electronic apparatus according to still another aspect of the invention includes the above device.

The above wiring pattern forming method using a droplet discharging method allows restraining migration from occurring at an end portion or a bent portion of a wiring pattern, thereby either restraining the occurrence of dendrites or controlling the growth direction of dendrites, thus preventing short circuit between lines.

Use of the above wiring pattern forming method further provides a device and an electronic apparatus that permit short circuit between lines to be prevented.

### BRIEF DESCRIPTION OF THE DRAWINGS

The invention will be described with reference to the accompanying drawings, wherein like numbers reference like elements.

FIG. 1 is a schematic view showing one example of a wiring pattern where dendrites have occurred.

FIG. 2 is a schematic perspective view showing a droplet discharging device used for a wiring pattern forming method according to one embodiment of the invention.

FIG. 3 is a schematic external view of a droplet discharging head according to one embodiment of the invention.

FIG. 4 is a pattern diagram to explain one example of the wiring pattern created by the wiring pattern forming method according to one embodiment of the invention.

FIG. 6A is a pattern diagram to explain one example of the wiring pattern forming method according to one embodiment of the invention.

FIG. 5B is a diagram showing one example of an enlarged view of point A shown in FIG. 5A.

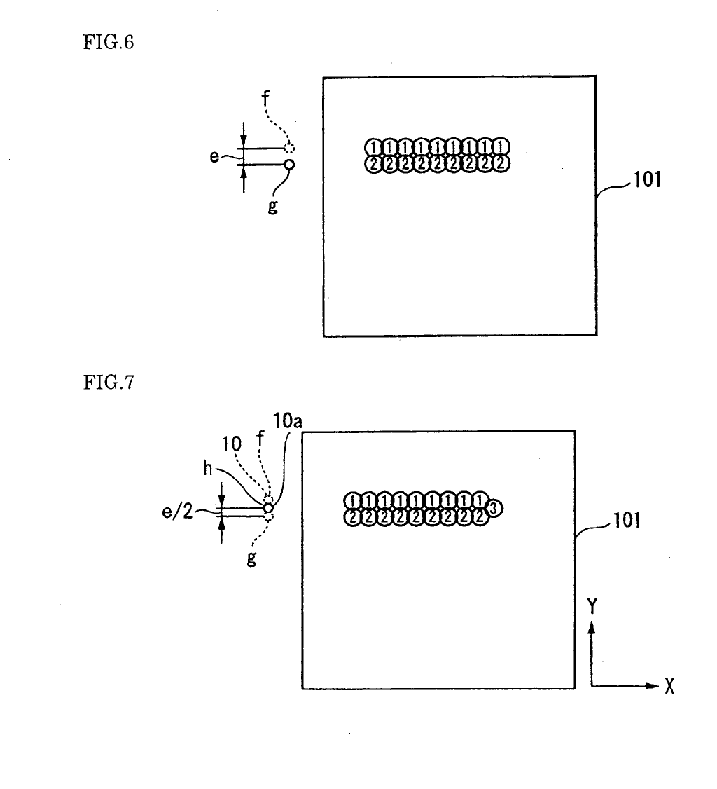

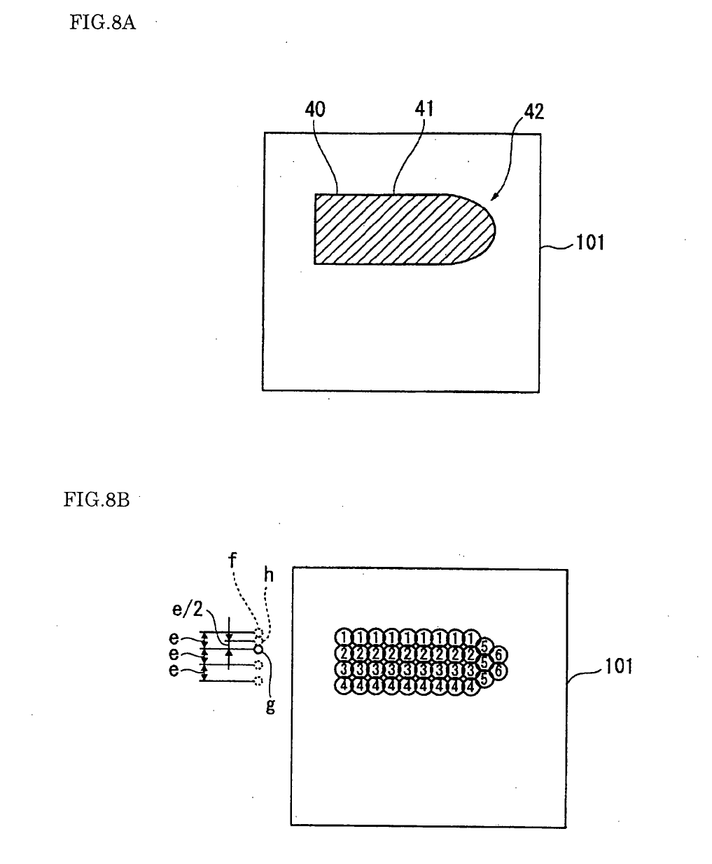

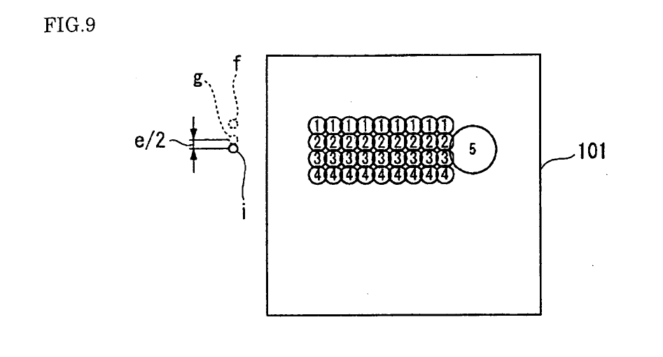

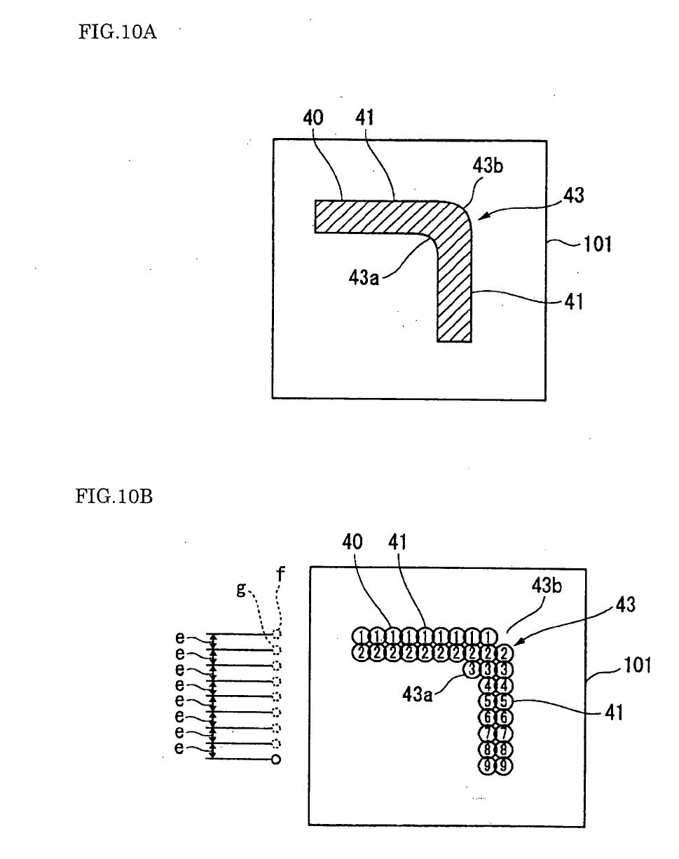

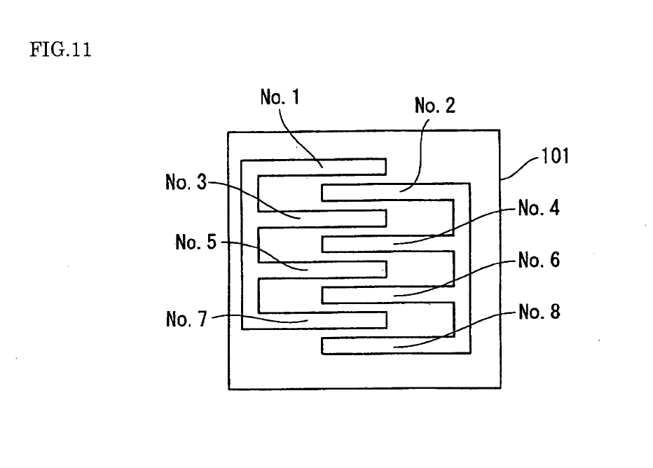

FIG. 6 is a pattern diagram to explain one example of the wiring pattern forming method according to one embodiment of the invention.

FIG. 7 is a pattern diagram to explain one example the wiring pattern forming method according to one embodiment of the invention.

FIG. 8A is a pattern diagram to explain one example of the wiring pattern created by the wiring pattern forming method according to one embodiment of the invention.

FIG. 8B is a pattern diagram to explain one example of the wiring pattern forming method according to one embodiment of the invention.

FIG. 9 is a pattern diagram to explain one example of the wiring pattern forming method according to one embodiment of the invention.

FIG. 10A is a pattern diagram to explain one example of the wiring pattern created by the wiring pattern forming method according to one embodiment of the invention.

FIG. 10B is a pattern diagram to explain one example of the wiring pattern forming method according to one embodiment of the invention.

FIG. 11 is a pattern diagram showing one example of the line wiring pattern created in a first working example and a first comparative example.

### DESCRIPTION OF EXEMPLARY EMBODIMENTS

Embodiments of the invention will be described.

### First Embodiment

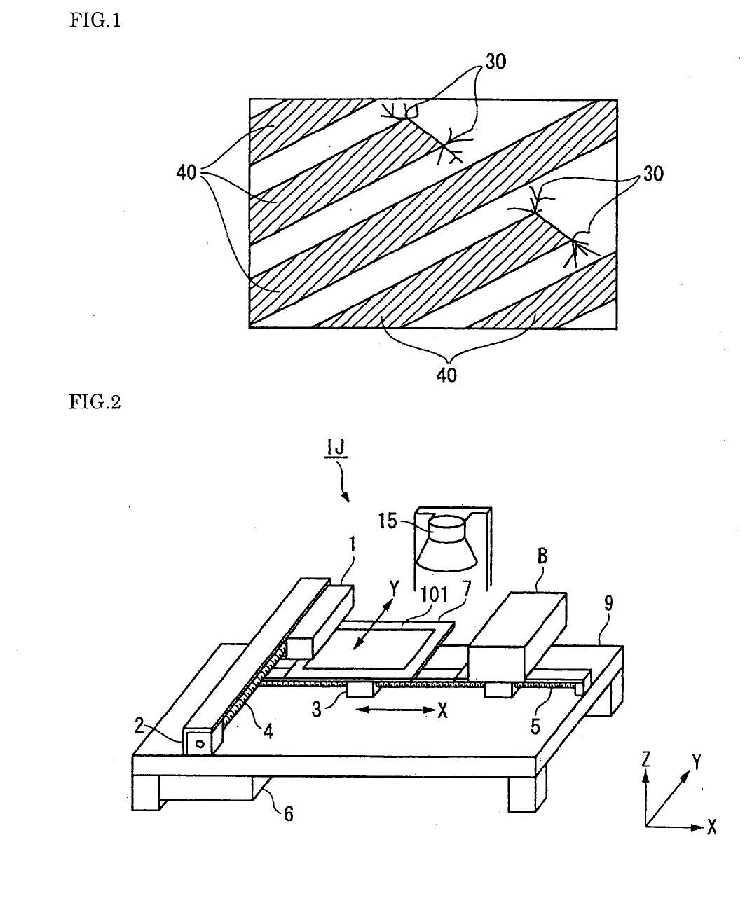

Referring to FIGS. 1A through 7, a first embodiment of the invention will now be described.

FIG. 2 is an external perspective view of a droplet discharging device IJ having a droplet discharging head 1 used in a wiring pattern forming method according to the present embodiment of the invention. In FIG. 2, the droplet discharging device IJ includes a droplet discharging head 1, an X-axis direction driving shaft 4, a Y-axis direction guiding shaft 5, a control device 6, a stage 7, a cleaning mechanism 8, a platform 9, and a heater 15. The stage 7, supporting a substrate 101 onto which droplets are discharged by the droplet discharging device IJ, includes an unillustrated fixing mechanism for fixing the substrate 101 on a reference position.

The droplet discharging head 1 is a multi-nozzle type droplet discharging head 1 having a plurality of discharging nozzles 10 that will be described later and having a long side that is in line with the Y-axis direction. The discharging nozzles 10 are provided underneath the droplet discharging head 1, being aligned in the Y-axis direction with a constant interval between each other. From the discharging nozzles 10 of the droplet discharging head 1, a liquid material containing fine conductive particles, for example, is discharged.

The droplet discharging head 1 allows the liquid material to be quantitatively discharged in droplets by the droplet discharging method. To illustrate, it is a device that allows 1 to 300 nanograms of the liquid material per one droplet to be quantitatively discharged in a continual manner.

The system to discharge the droplets may be a piezoelectric jet system in which the liquid material is discharged by changes in the volume of a piezoelectric element, or it may also be a system in which heat is applied to rapidly produce steam for discharging the liquid material.

The above described liquid material refers to a medium having a viscosity that allows the liquid material to be discharged from the discharging nozzles 10 of the droplet discharging head 1, whether the medium be aqueous or unctuous. The medium needs only to have a sufficient fluidity, or viscosity, that allows it to be discharged from nozzles, or the like. The medium may also contain some solid substances mixed into it if only it is fluid as a whole. Furthermore, besides fine particles dispersed in a solvent, the materials that may be contained in the liquid material include a dissolved substance heated to exceed the melting point and a dye stuff, a pigment or any other high performance material added to a solvent. In addition, the substrate 101 refers to a flat substrate, but it may also be a substrate with a rounded surface. Moreover, the pattern forming surface does not need to be hard. Besides metals, it may also be a surface of a flexible material such as film, paper, rubber, or the like.

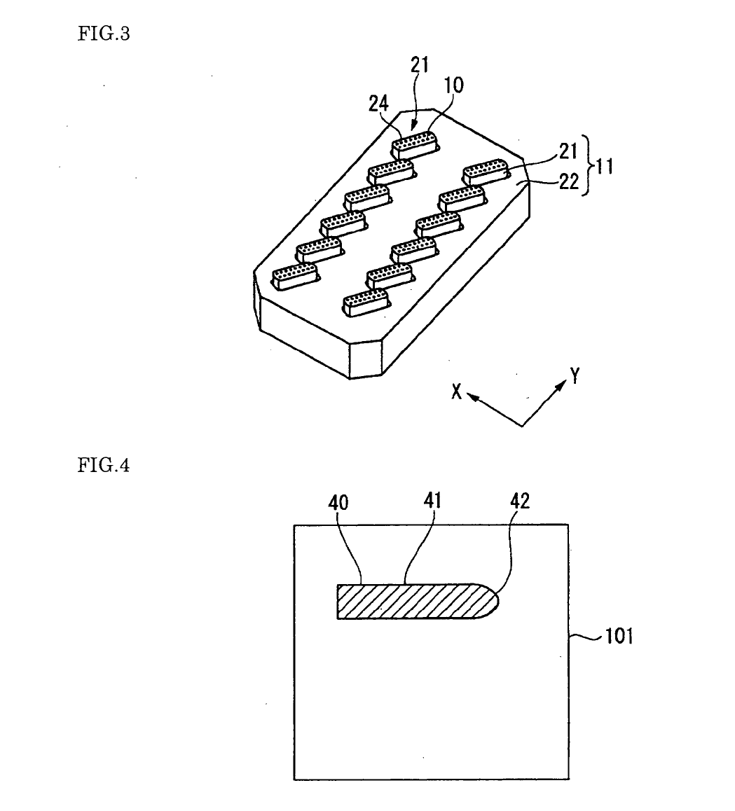

FIG. 3 is a diagram showing the droplet discharging head 1 observed from the side of the nozzle face 24 (i.e. from the side of the face that is opposed to the substrate 101). The droplet discharging head 1 includes a plurality of head sections 21 and a carriage section 22 mounted with the head sections 21. A plurality of discharging nozzles 10 for discharging the liquid material in droplets are provided on the nozzle face 24 of the head section 21. Each of the head sections 21 (the nozzle face 24) has a rectangular shape as observed in a plan view and is provided with the plurality of discharging nozzles 10 that are aligned in such a manner that they lie uniformly spaced along the long side of the head section 21, approximately along the Y-axis direction, and in two rows that are spaced approximately along the X-axis direction that is in line with the width of the head section 21. For example, 180 nozzles in each row and 360 nozzles in total may be provided on each of the head sections 21. Furthermore, a plurality of head sections 21 are positioned on the carriage section 22 to be supported by it, with their discharging nozzles 10 facing the substrate 101. The head sections 21 are aligned approximately along the Y-axis direction in such a manner that they are tilted by a predetermined degree with reference to the Y axis, and in two rows with a predetermined spacing provided along the X-axis direction between each other. In FIG. 3, six head sections in a row and twelve head sections in total are provided on the carriage section 22.

Here, the droplet discharging head 1 includes an angle adjusting mechanism (not illustrated) that allows the mounting angle of the droplet discharging head 1 to be adjusted with reference to Y axis. The angle adjusting mechanism renders the angle θ variable, which is the angle that the droplet discharging head 1 makes with Y axis. The angle adjusting mechanism being driven allows each of the discharging nozzles 10 to be disposed in array along the Y-axis direction. It also allows the angle of the discharging nozzles 10 to be adjusted with reference to Y axis.

In FIG. 2 again, an X-axis direction driving motor 2 is connected to the X-axis direction driving shaft 4. The X-axis direction driving motor 2 is, for example, a stepping motor, and rotates the X-axis direction driving shaft 4 when X-axis direction driving signals are supplied from the control device 6. When the X-axis direction driving shaft 4 rotates, it moves the droplet discharging head 1 in the X-axis direction.

The Y-axis direction guiding shaft 5 is fixed so as not to move with respect to the platform 9. The stage 7 is provided with the Y-axis direction driving motor 3. The Y-axis direction driving motor 3 is a stepping motor, for example, and moves the stage 7 in the Y-axis direction when Y-axis direction driving signals are supplied from the control device 6.

The control device 6 supplies voltage for controlling discharge of droplets to the droplet discharging head 1. Also, it supplies driving pulse signals to the X-axis direction driving motor 2 for controlling the move of the droplet discharging head 1 in the X-axis direction, as well as supplying driving pulse signals to the Y-axis direction driving motor 3 for controlling the move of the stage 7 in the Y-axis direction.

The above mechanism allows the droplet discharging device IJ to discharge droplets onto the substrate 101 while it relatively scans the droplet discharging head 1 and the stage 7 that supports the substrate 101.

The cleaning mechanism 8 serves to clean the droplet discharging head 1. The cleaning mechanism 8 is provided with a driving motor, not illustrated, that drives in the Y-axis direction. The cleaning mechanism 8, being driven by the driving motor in the Y-axis direction, moves along the Y-axis direction guiding shaft 5. The move of the cleaning mechanism 8 is also controlled by the control device 6.

The heater 15 here is a unit that serves for heat treating the substrate 101 by ramping anneal. It vaporizes and dries the solvent contained in the liquid material applied on the substrate 101. Turning on and off of power supply to the heater 15 is also controlled by the heating device 6.

In the present embodiment, the droplet discharging device IJ forms a wiring pattern on the substrate 101. Therefore, fine conductive particles are contained in the liquid material as a material for forming a wiring pattern. The liquid material is made of the fine conductive particles that have been pasted with a predetermined solvent and a binder resin. Fine particles of gold, silver, copper, iron and such other metals may be used as the fine conductive particles. It is preferable that the particle size of the fine conductive particles be 5 to 100 nm. The liquid material discharged onto the substrate 101 from the droplet discharging head 1 is converted into a conductive film through heat treatment by the heater 15.

Furthermore, the liquid material for forming the wiring pattern may contain an organic metal compound, an organic metal complex and some other substance of the type. In the case where an organic silver compound is used as the organic metal compound, the organic silver compound is dispersed or dissolved in a solvent, such as diethylene glycol diethyl ether, to be used as the liquid material. If the fluid is further treated with heat or light, the organic compound ingredient is eliminated, thereby leaving silver particles behind and, thus, leading to expression of conductivity.

Now, a wiring pattern forming method according to the present embodiment will be described.

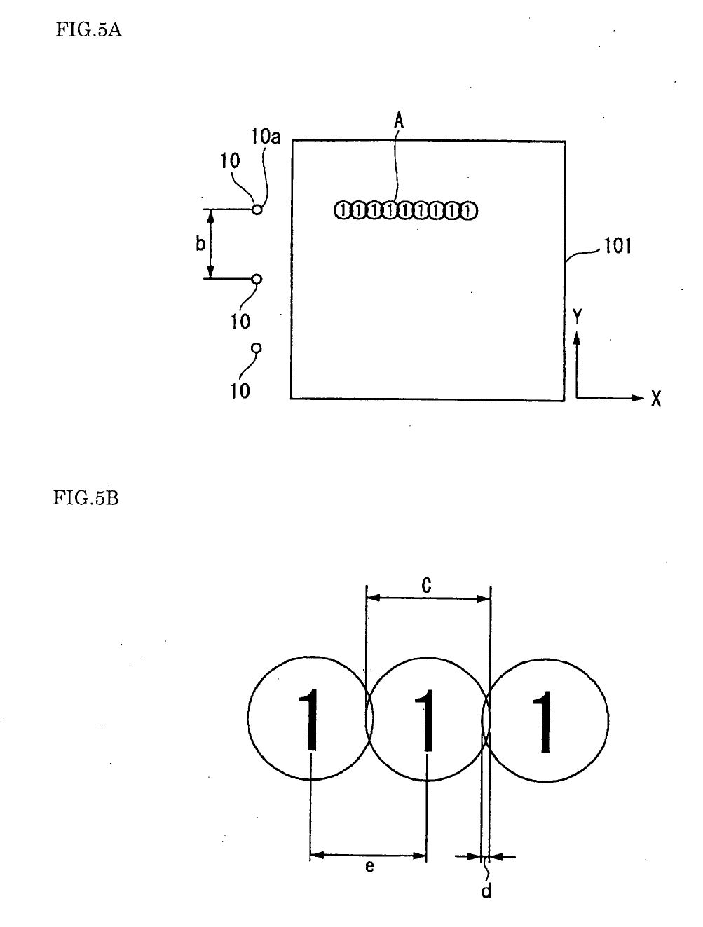

FIG. 4 is a pattern diagram showing one example of a wiring pattern 40 formed by the wiring pattern forming method according to the present embodiment. The wiring pattern 40 includes a body portion 41 and an end portion 42. Referring to FIGS. 5A through 7, the wiring pattern forming method will be described.

FIG. 5A is a pattern diagram showing droplets that have been discharged onto the substrate 101 placed on the stage 7 from a discharging nozzle 10a provided on the droplet discharging head 1, the droplet discharging head 1 and the stage 7 having been moved (first scan). The droplets discharged by the first scan are each represented by the number “1”. The droplet discharging head 1 is set up in such a manner that its long side is in line with the Y-axis direction and the discharging nozzles 10 are provided on the droplet discharging head 1 along the Y-axis direction, with a uniform spacing b between each other.

FIG. 5B is a diagram that shows one example of enlarged view of the droplets at point A shown in FIG. 5A. The droplets, having been discharged onto the substrate 101, spread on the substrate 101 when they land there. For example, the droplets that have landed on the substrate 101 spread there in such a manner that their diameter is c. The diameter c of the above described droplets is determined in accordance with a variety of conditions, including the type of the liquid material used, the wettability of the substrate 101 with respect to the above described liquid material, the substrate temperature, the shape and the size of the discharging nozzles 10, and so on.

As the droplet discharging head 1 scans in the X-axis direction, it discharges droplets from the discharging nozzles 10 provided on it onto the substrate 101. At this time, the droplets are discharged in the X-axis direction with the control of the control device 6 in such a manner that a predetermined spacing is provided between the droplets. In the present embodiment, the droplet discharge spacing e is set to be 0.9×c. This means that each of the droplets formed on the substrate 101 overlaps with adjacent droplets by as much as 10% of their length in the diametrical direction of the droplets. This allows the void sections created in a wiring pattern, when it is formed, by the round shape of the droplets, to be filled by spread of the part of overlapped length d of each of the droplets. It also allows the swell formed by excess liquid material, referred to as the bulge, to be prevented.

In FIGS. 5A and 5B, the adjacent droplets are disposed in such a manner that they overlap with each other by as much as 10% of their length in the diametrical direction, the overlapped length d being determined to have a most suitable value in consideration of various conditions including the properties of the liquid material, the wettability of the substrate regarding the liquid material, the substrate temperature, the shape and the size of the nozzles, and the like. In general, the overlapped length d is preferably set at a value that ranges from 1% to 30%. This is due to the fact that discharge of droplets under excessively overlapping conditions may lead to unpreferable creation of the swell formed by excess liquid material, called the bulge.

FIG. 6 is a pattern diagram showing one example of second scan in which droplets are discharged from the discharging nozzle 10a onto the substrate 101. Initially, the stage 7 is stepping moved in the Y-axis direction by as much as the droplet discharge spacing e in order to render the discharging nozzle 10a to be moved from the initial position f to position g. Then, the droplet discharging head 1 is made to scan in the X-axis direction to discharge droplets with the droplet discharge spacing e between each other, in the same manner as in the first scan. The droplets discharged by the second scan are assigned the number “2”.

FIG. 7 is a pattern diagram showing one example of the wiring pattern 40 the end portion 42 of which is made into a tapered shape. Initially, the stage 7 is stepping moved in the—Y-axis direction by as much as e/2 (hereinafter referred to as half a pitch) in order for the discharging nozzle 10a to be moved from position g to position h. Then, the droplet discharging head 1 is moved to the end portion 42 of the wiring pattern 40 for discharge of droplets. The droplets discharged by this third scan are assigned the number “3”. In this way, the wiring pattern 40 according to the embodiment shown in FIG. 4 is formed.

### Second Embodiment

FIG. 8A is a pattern diagram showing another example of the wiring pattern 40 formed by using the wiring pattern forming method according to the embodiment of the invention. The wiring pattern 40 includes the body portion 41 and the end portion 42, the end portion being made into a tapered shape. Referring to FIG. 8B, the wiring pattern forming method will be described.

The body portion 41 of the wiring pattern 40 is formed in the same way as in the case of the previous embodiment. Namely, droplet discharging head 1 is first run from the initial position f to scan in the X-axis direction and discharge droplets with the droplet discharge spacing e between each other (first scan). Then, the stage 7 is moved in the Y-axis direction by as much as the droplet discharge spacing e to move the discharging nozzle 10a from position f to position g. Then, the droplet discharging head 1 is made to scan in the X-axis direction to discharge droplets with the droplet discharge spacing e between each other (second scan). The above described operation is repeated to perform a third scan and a fourth scan, thereby forming the body portion 41 of the wiring pattern 40 according to the present embodiment.

Next, the discharging nozzle 10a is moved to position h. Position h is the position to which the stage 7 is stepping moved from the initial position g by as much as half a pitch in the—Y-axis direction. Then, after the discharging nozzle 10a has been moved to the end portion 42 of the wiring pattern 40, it is made to scan the substrate 101 in the Y-axis direction, thereby discharging droplets with the droplet discharge spacing e between each other. The droplets discharged by this fifth scan are assigned the number “5”.

Furthermore, the discharging nozzle 10a is moved to position g. Then, after the discharging nozzle 10a has been moved to the end portion 42 of the wiring pattern 40, it is made to scan the substrate 101 in the Y-axis direction, thereby discharging droplets with the droplet discharge spacing e between each other. The droplets discharged by this sixth scan are assigned the number “6”. The wiring pattern 40 according to the embodiment shown in FIG. 8 is formed in the above described manner.

### Third Embodiment

FIG. 9 is a pattern diagram showing one example of another method to create the wiring pattern 40 shown in FIG. 8A. The body portion 41 of the wiring pattern 40 is created by a method that is similar to the method according to the above described embodiment. Then, the discharging nozzle 10a is moved to position i. Position i is the position to which the stage 7 is stepping moved in the—Y-axis direction from the initial position g by as much as half a pitch. Then, after the droplet discharging head 1 is moved to the end portion 42 of the wiring pattern 40, a droplet is discharged (fifth scan). At this time, a droplet having a droplet diameter c that is larger than previous droplets is discharged by increase in the volume of the discharged droplet. In this manner, the end portion 42 of the wiring pattern 40 can be made into a tapered shape.

### Fourth Embodiment

FIG. 10A is a pattern diagram showing another example of a wiring pattern 40 formed by using the wiring pattern forming method according to the present embodiment. The wiring pattern 40 includes two body portions 41 and a curved bent portion 43, the body portions 41 being positioned in directions that intersect each other and the bent portion 43 coupling the body portions. Referring to FIG. 10B, the wiring pattern forming method will be described.

FIG. 10B is a pattern diagram showing droplets discharged on the substrate 101 from the discharging nozzle 10a. In the same way as in the previous embodiment, the droplet discharging head 1 is initially run from the initial position f to scan in the X-axis direction, thereby discharging droplets (first scan). Then, after the stage 7 is moved in the Y-axis direction by as much as the droplet discharge spacing e and the discharging nozzle 10a is moved from position f to position g, the droplet discharging head 1 is run to scan in the X-axis direction, thereby discharging droplets with the droplet discharge spacing e between each other (second scan). The above described operation is repeated to perform the third through to the ninth scans, thereby forming the wiring pattern 40 according to the present embodiment. The droplets discharged by an n^{tb} scan are assigned the sign “n”.

Meanwhile, at the bent part 43 of the above described wiring pattern 40, the outer line of the wiring is made to have a curved shape with one droplet being discarded, thereby forming an outer bent part 43b. Conversely, one droplet is added to the inner bent part 43a, thereby making the inner line of the wiring to have a curved shape. Here, the number of droplets increased or decreased is not limited to one, and the outer line of the wiring is set so as to have a gentler curve, depending on the width, the shape, and the like, of the wiring pattern.

The effects to be obtained by the embodiments of the invention will be described.

The wiring pattern forming method according to the embodiments of the invention includes a further step to provide the end portion 42, or the bent portion 43, of the wiring pattern 40 with a tapered shape, in addition to relatively moving the droplet discharging head 1 and the substrate 101 in predetermined directions, discharging the liquid material onto the above described substrate 101 from a plurality of discharging nozzles 10 provided on the droplet discharging head 1, and depositing a predetermined wiring pattern 40 on the substrate 101. In the case where the wiring pattern 40 has an acutely angled end portion 42, or bent portion 43, this structure allows a local electric field occurring at the part of the acutely angled periphery of the end portion 42, or the bent portion 43, to be eliminated at the time when an electric field is impressed to the wiring pattern 40 to flow currents. As a result, this restrains the migration of an impurity metal, or the like, from being caused by the local electric field, thereby restraining occurrence of dendrites and preventing short circuit occurring between lines.

In the case where the wiring pattern 40 has a bent portion 43, if the bent portion is made to have a curved external form by control of the discharge pattern of droplets at the bent portion 43, the occurrence of migration and, thus, of dendrites can be restrained, thereby leading to the prevention of short circuit between lines.

Additionally, a device that permits short circuit between lines to be restrained can also be made using the wiring pattern forming method according to the embodiment of the invention. Furthermore, an electronic apparatus employing the device can also be made. The device according to the embodiment of the invention includes an element and a unit having predetermined wiring patterns.

### WORKING EXAMPLES

The invention will be described on the basis of a working example. The working example, however, does not limit the scope of the invention.

Five plastic substrates, having gone through a predetermined cleaning process, were prepared. The five substrates were set at a predetermined position of droplet discharging devices. As FIG. 11 shows, two sets of interdigital line wiring patterns, each having a set of four teeth of comb, were formed on each of the substrates, facing each other. The line wiring patterns on each substrate were referred to from above as a first line wiring pattern, then a second, a third, and so on, down to an eighth line wiring pattern. Here, the line wiring patterns were each formed with a size of 120 μm in the width and 10 mm in the length, while being provided with a spacing of 30 μm between each other.

On each substrate, the body portions of the line wiring patterns were formed by discharge of droplets, each having a weight of 7 ng, in a serial manner every 36 μm in the scan direction from eight droplet nozzles that were provided in an array with a spacing of 240 μm between each other. On the plastic substrates, each droplet weighing 7 ng formed a droplet having a diameter of 40 μm.

The body portion of each of the line wiring patterns was composed of four droplets in the width direction. At the end portion of the body portion, the number of droplets was decreased step by step to three, then to two, and the like. At the same time, the stage was shifted in each of the steps by as much as half a pitch (i.e. 18 μm), thereby forming a tapered shape of the end portion.

A negative electrode was connected to line wiring patterns having odd numbers while a positive electrode was connected to line wiring patterns having even numbers, and an electric field of 3 V/μm and a voltage of 90 V were impressed for 15 minutes. After the electric field was impressed, the peripheral portions of the line wiring patterns were observed, to find out no change there.

In a comparative example, line wiring patterns were formed on five substrates in the same manner as in the working example, except that the end portions of the line wiring patterns were not formed in a tapered shape.

Similar to the working example, a negative electrode was connected to line wiring patterns having odd numbers while a positive electrode was connected to line wiring patterns having even numbers, and an electric field of 3 V/μm and a voltage of 90 V were impressed for 15 minutes. In one of the five substrates, line-to-line short circuits occurred in 4 lines. In addition, it was found out by an electronic microscopic observation that a planar tree structure of a deposited impurity, referred to as the dendrite, was produced at the end portion of every line wiring pattern on each of the five substrates.

The present invention relates to a wiring pattern forming method using a liquid material that is discharged in the form of droplets from a droplet discharging head onto a substrate. For printed substrates, the invention may be applied to any wiring pattern in which electric currents having different voltage polarities are flowed between adjacent lines. Examples of application include an interdigital electrode of a SAW filter and a blood sugar sensor.

The entire disclosure of Japanese Patent Application No. 2006-321472, filed Nov. 29, 2006 is expressly incorporated by reference herein.

What is claimed is:

1. A wiring pattern forming method, comprising:
relatively moving a droplet discharging head and a substrate, each in a predetermined direction;
discharging a liquid material in a form of droplet onto the substrate from a plurality of discharging nozzles formed on the droplet discharging head;
forming a predetermined wiring pattern on the substrate; and
forming an end portion of a wiring pattern in a tapered shape, or a bent portion of a wiring pattern in a curved shape.

2. The wiring pattern forming method according to claim 1, further comprising; forming the end portion of the wiring pattern in a tapered shape through step-by-step decrease in number of droplet discharge in the scan direction of the wiring pattern and step-by-step shift of a position for droplet discharge by as much as half a pitch per step in the non-scan direction.

3. The wiring pattern forming method according to claim 1, further comprising; forming the bent portion of the wiring pattern in a curved shape through increase and decrease in number of droplet discharge at the bent portion.

4. A device comprising a predetermined wiring pattern formed on a substrate by the wiring pattern forming method according to claim 1.

5. An electronic apparatus comprising the device according to claim 4.
